(19) United States
(12) Patent Application Publication
(10) Pub. No.: US 2004/0216674 A1
(43) Pub. Date: Nov. 4, 2004

(54) Wafer jar loader method, system and apparatus

(76) Inventors: Frank V. Linker II, Springfield, PA (US); Frank V. Linker JR., Broomall, PA (US)

Correspondence Address: Eugene E. Renz, Jr., P.C., 205 North Monroe Street, Post Office Box 2056, Media, PA, 19063-9056, US

(21) Appl. No.: 10/856,154

(22) Filed: May 27, 2004

Related U.S. Application Data
(63) Continuation of application No. 10/192,992, filed on Jul. 11, 2002, now abandoned.
(60) Provisional application No. 60/304,904, filed on Jul. 12, 2001.

(51) Int. Cl. C23C 16/00

(52) U.S. Cl. 118/719

(57) ABSTRACT

1. A method for packaging wafers having a bottom side and a top circuit side in jars comprising the steps of

placing a cassette having a plurality of pockets for wafers at the back side facing upwardly, transferring the top wafer in the cassette by means of a vacuum suction mechanism which centers the top wafer in the cassette pocket upon initial engagement and then transfers and discharges the wafer in a jar located at a jar station and feeding interleafs in timed relation to the wafer feed so that an interleaf is positioned between each wafer loaded in a jar.

### BACKGROUND OF THE INVENTION

These wafers are very fragile and expensive, some wafers being valued in the order of $10,000.00 and accordingly, equipment of the type to which the present invention relates must be capable of handling the wafers very carefully to minimize damage. In accordance with some prior art systems, the wafer holder cassette is placed in the loader with the circuit side of the wafer facing upwardly and then removed from the pockets in the cassette by apparatus which engages under a wafer in the cassette to withdraw it and then rotates the wafer so that the bottom faces upwardly before it is discharged into the wafer jar container. Paper liners are interleaved between the wafers stacked in the wafer jar container by mechanism including a suction cup or vacuum system which limits the type of interleaf material that can be used and eliminates some form of economic porous papers which would serve the purpose adequately from separating the wafers in the wafer jar container.

### SUMMARY OF THE INVENTION

With the foregoing in mind, it is an object of the present invention to provide a system and apparatus for automatically removing wafers from cassettes and safely loading them into shipping jars wherein characterized by novel features of construction and arrangement providing a system which transfers the wafers quickly and safely virtually eliminating counting errors and mishandling of wafers.

In the system of the present invention the cassettes are mounted at a loading station with the H-bar facing up which orientation presents the bottom non-circuit side of the wafers and thus eliminating the need to rotate wafers in the transfer process. Accordingly, wafers are picked up from the back side and therefore jar loading is smoother and faster and the risk of mishandling of wafers is further reduced.

More specifically, the wafer transfer mechanism of the present invention utilizes a vacuum pick and place arm mechanism with a vacuum generator built in integrally to provide a linear transfer, which is smooth and vibration free one wherein the wafers are levitated in the initial transfer cycle so that they do not engage the ribs defining the wafer pockets in the cassette and wherein the wafer is released and gently guided into the jar to ensure safe, accurate, even placement.

The wafer jar container is positioned on a shelf at the wafer loading station that is easily retractable for easy access and incorporates mounting guides which ensure proper jar positioning. The configuration is such that it accommodates all popular styles of jar containers.

Another feature of the system and apparatus of the present invention is the particular configuration and arrangement of the interleaf loading chamber and interleaf chute and the means for storing and discharging one interleaf at a time in timed relation with the wafer transfer mechanism so that interleaves are positioned quickly and accurately in the jar container between all of the wafers during a loading cycle. The pull out chamber holds up to 500 interleaves and the system is designed to accommodate either porous or non-porous interleaves which are carbon based. As explained in detail, hereinafter, the system is set up for maintaining automatic pressure on the stack of interleaves and includes a low paper sensor signal which signals the operator when reloading is required. The interleaf chute assembly is characterized by novel features of construction and arrangement whereby interleaves are fed into the chute until a wafer is in a jar and when the interleaf is released, advanced interleaf placement technology insures accurate, gentle insertion of the interleaves into the jar.

Summarizing the features of the Wafer Jar loader System and Apparatus of the present invention, the system has a high capacity and is capable of loading 10 wafers per minute, it accommodates all styles of commonly used jar containers up to 3 ⅛ inch deep, accepts all popular styles of wafer holder cassettes and runs porous tyvek or non carbon based interleaves.

The apparatus is rather simple and compact in design and presents a clear operator view to the wafer transfer process by reason of a see-through plexidome housing which protects the wafers without obscuring visibility. The main controls of the system are easy to access and the short cassette to jar distance maximizes through put and minimizes the chances of mishandling and damage to wafers.

### BRIEF DESCRIPTION OF THE DRAWINGS

These and other objects of the present invention and the various features and details of the operation and construction thereof are hereinafter more fully set forth with reference to the accompanying drawings, wherein;

FIG. 1 is a plan top view of the Wafer Jar Loading system showing the functional stations and operating elements;

FIG. 2 is a sectional view taken along line A-A of FIG. 1 showing details of the Wafer Jar Loading system;

FIG. 3 is a side and top plan view of an inverted cassette showing the H-Bar upward and used as a datum for registering the cassette and wafers;

FIG. 4 is a schematic which illustrates of the sequence and order of a typical wafer jar container loading process. Major elements of the loading process are shown removed from the system for clarity of operation. The sequence is automatically continued until all wafers are loaded into a shipping container jar. The operator then reloads wafers, container jar, and interleaf material to start another loading process;

FIG. 5A is a side view of a cassette;

FIG. 5B is a side view of a cassette holder;

FIG. 6A is a side elevation view of a cassette installed in a cassette holder with lever and cam mechanism in an unseated position;

FIG. 6B is a side elevation view of a cassette installed in a cassette holder with lever and cam mechanism in a seated position;

FIG. 7A is a detail of holder switch indicating that cassette in an unseated position;

FIG. 7B is a detail of holder switch indicating that cassette is in the seated position;

FIG. 8 is a side elevation view partly in section showing the spring biasing means for normally biasing the wafer locating plate in operative limit position;

FIG. 9 is a top plan view with parts broken away of the cassette and the wafer seating assembly into limit positions;

FIG. 10 is a top plan view of the transfer pickup station showing extreme limit positions for the suction pickup;

FIG. 11 is a transverse sectional view taken of lines 11-11 of FIG. 10;

FIG. 12 is a side elevational view of the suction pickup and wafer cassette prior to activation of the suction cup to engage the uppermost wafer in the cassette;

FIG. 13 is a view similar to FIG. 12 showing the details of the vacuum transfer mechanism;

FIG. 14 is an enlarged transverse sectional view through the shipping container or jar;

FIG. 15 is a fragmentary view showing the suction pickup engaging the uppermost wafer;

FIG. 16 is a fragmentary view showing the gap sensor and flag which determines the engaging stroke of the suction pickup;

FIG. 17 is a fragmentary view showing automatic centering of the uppermost wafer when vacuum is applied to the cup;

FIGS. 18, 19, 20 are transverse sectional views of another embodiment of suction vacuum pickup device in accordance with the present invention;

FIG. 21 is a view showing the cup mounted on the section pickup arm;

FIG. 22 is a fragmentary sectional view showing the suction pickup showing the second embodiment of a suction pickup engaging the uppermost wafer in the cassette;

FIG. 23 is a fragmentary view showing the centering function;

FIG. 24 is a view of the control panel;

FIG. 25 is a perspective view of a wafer non-inverted cassette;(inverted cassette)

FIG. 26 is a fragmentary perspective view showing some of the details of the interleaf station;

FIG. 27 is a perspective interleaf station showing the interleaf storage container;

FIG. 28 a plan view of the interleaf station;

FIG. 29 is a fragmentary section taken on lines 29-29 of FIG. 28 showing a slide drawer;

FIG. 30 is a sectional view taken on lines 30B-30B of FIG. 30A;

FIG. 30A is a transverse sectional view showing the interleaf loading mechanism;

FIG. 31 show the switches for the cam nut design featured in FIG. 30;

FIG. 32 is a bottom plan view of the pulley for activating the leafs through on the interleaf lift mechanism;

FIG. 33 is an enlarged sectional view showing the interleaf stack and wheel runner;

FIG. 34 is a fragmentary sectional view similar to FIG. 33 showing the wheel runner in its initial retract position to condition the uppermost interleaf for discharge from the stack;

FIG. 35 is a perspective view of the portion of the interleaf mechanism for taken on lines G-G of FIG. 34;

FIG. 36 is a fragmentary view showing the wheel runner advancing the uppermost interleaf to positioned where it can be discharged down the chute to the jar;

FIG. 37 is a perspective view showing the interleaf in position to be discharged to the jar; and

FIG. 38 is a view showing the interleaf discharging into the jar.

### DETAILED DESCRIPTION OF THE PREFERRED EMBODIMENTS

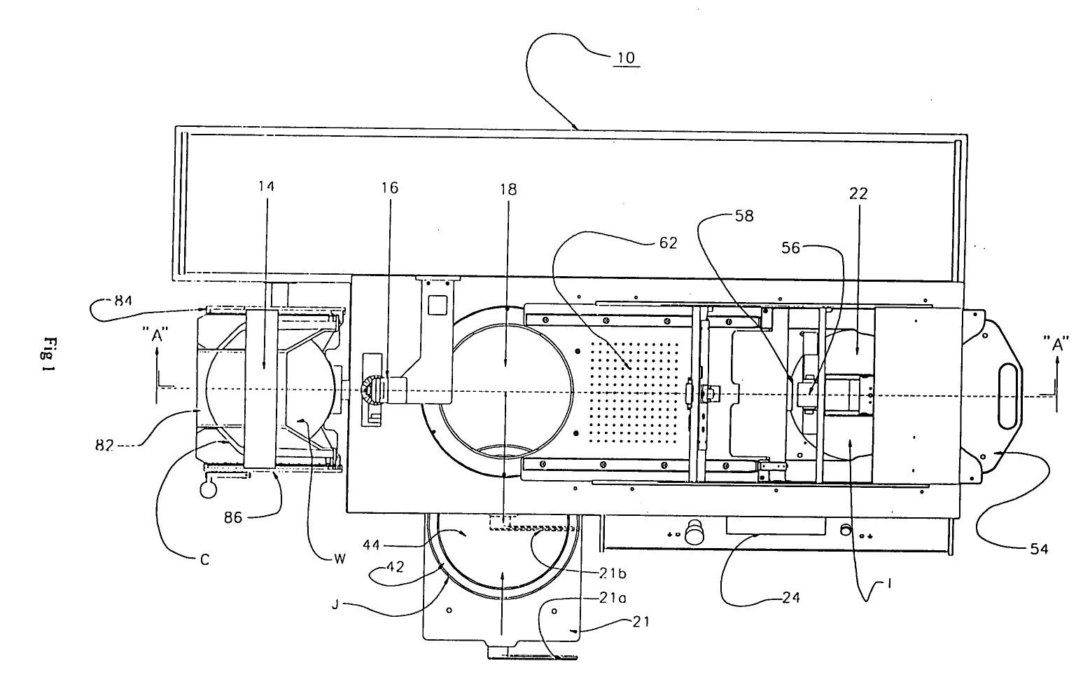

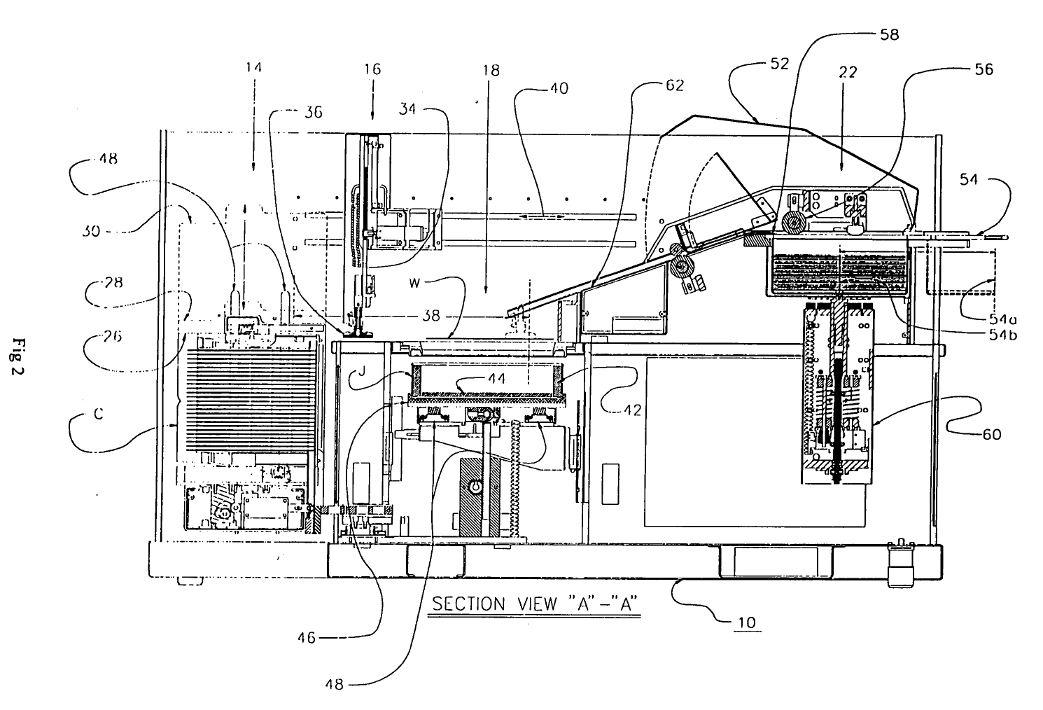

Referring now to FIGS. 1 and 2, there is shown a top plan view and a side section view respectively of a system and apparatus 10 for packaging wafers W in shipping containers J. The system 10 is shown removed form its housing and comprises a cassette loading station 14, a transfer pickup station 16, for removing wafers W from cassettes C, a shipping container station 18 with pull out shelf 21 to position containers for loading, a slide drawer interleaf station 22, and an operator control station that initiates the automatic sequencing of alternately placing wafers W and interleafs I into shipping containers J as well as controlling and monitoring all other functions.

In FIG. 2 three cassette loading positions are shown; an initial load position 26, a wafer number 1, load position 28, and a wafer number 25, load position 30. As wafers W are transferred to the shipping container J, the cassette C is incrementally raised by cassette lift mechanism. Wafers W are transferred from cassette C to shipping container J as the pickup arm 34 with pickup cup 36 traverses distance 38 along a horizontal track 40 depositing wafers W in a shipping container J. FIG. 1 shows a shipping container J on pull out shelf 21 in two positions; with the pull out shelf extended as at 21^{a} and seated as at 21^{b}. The shipping container J generally contains a foam ring 42 around the internal periphery and a foam bottom pad 44 to cushion and protect wafers W. Pull out shelf 21 sits on positioning mechanism 46 that rides along two horizontal tracks 48. Interleaf slide drawer is shown with cover 52 raised and is comprised of a slide drawer 54 for a supply of interleafs 1, an interleaf feed wheel 56 and peel blade 58, an interleaf lift mechanism 60, and an interleaf chute 62. Slide drawer 54 is shown in an open position 54^{a} and seated position 54^{b}.

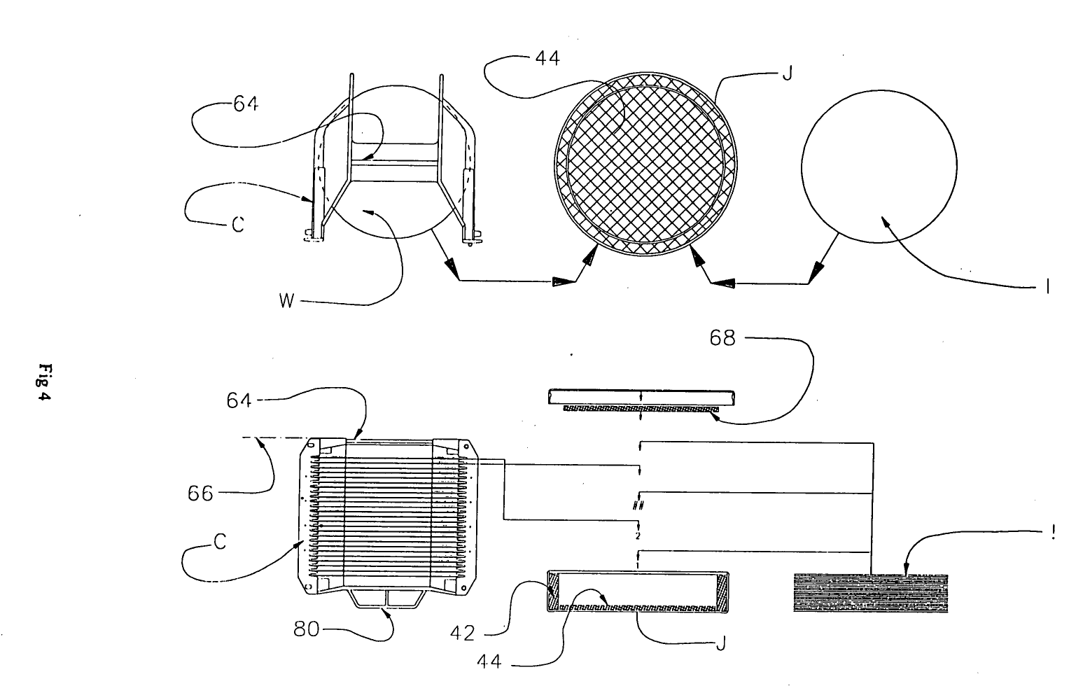

Considering the system and apparatus in terms of function and referring to FIGS. 1 and 2, wafers W housed in a conventional cassette C are transferred one at a time from the cassette C to the shipping container J. In accordance with the present invention, the cassette C is positioned so that the wafer's circuit sides are down facilitating easy and rapid transfer of wafers W from the cassette C to the shipping container J without the need for expensive and complicated robotics to rotate wafers. To facilitate understanding of the following embodiment, a schematic representation of the container loading sequence is shown in FIGS. 4, 10 and 11. FIG. 4 shows a wafer cassette C having a transport handle, a so-called H-Bar 64 which also provides the loading surface datum 66. A typical shipping container J with foam pad ring 42 and foam pad disc 44 is inserted to protect wafers W during loading and shipping. As illustrated, container loading is achieved in a predetermined sequence. A disc-like interleaf I is first inserted (interleaf No. 1) followed by a wafer W (wafer No.1). This sequence and order repeats until the desired number (N) of wafers W have been placed in container J. When wafer w (No. N) is placed into container J one more interleaf I (No. N+1) is placed into container J. The container J is removed and foam filler pads 68 are placed inside container J to fill remaining space above wafer W (No. N) before installing container lid.

Wafers W have two flat surfaces with one being the back and the other being the circuit side. The nominal wafer orientation in cassettes C is with the backside facing toward the bottom and the circuit side facing up. However, packaging in containers J require the circuit side facing down towards the container bottom. With the backside facing upwardly unpacking wafers W is easier and more rapid since only the back surface can be handled leaving the circuit side untouched. Unique to the present invention is the upside down and inverted positioning of the cassette C, eliminating the need to flip the wafer upside down for placement into the container J. This simplifies the automation process, speeds the loading and more importantly reduces handling.

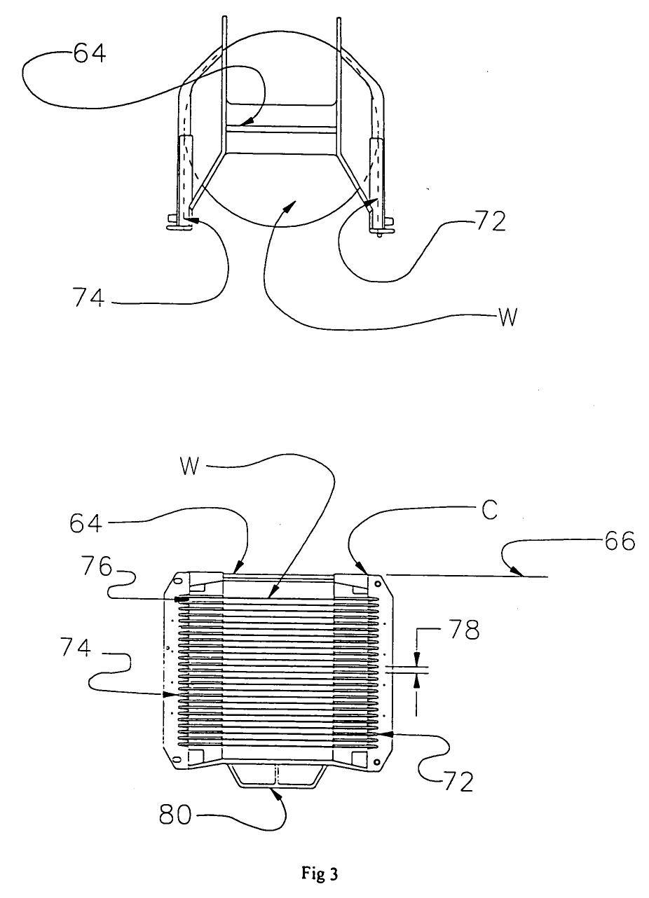

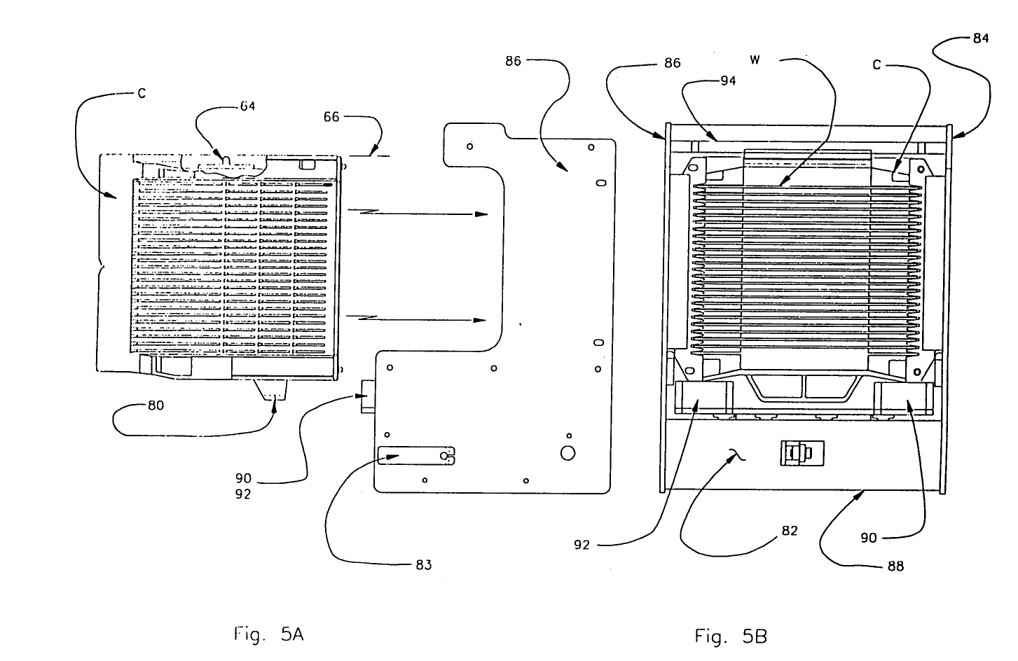

The cassette loading station 14 is comprised of a wafer cassette C illustrated in FIG. 1 and 2, a cassette holder 82 shown in FIG. 5A, 5B, 6A, and 6B, and a cassette lift mechanism. The wafer cassette C is of conventional design and typically made of a plastic material and has a pair of sidewalls 72 and 74 and a series of ribs 26 which define pockets 78 for the wafers W. A clearance between wafers W (see FIG. 3) and the pockets 78 allow wafers W to be removed from the pockets 78 without damage. The cassette C is positioned so that the H-Bar 64 is facing up thereby locating surface datum 66 in an upward position with the transport handle 80 in a downward position.

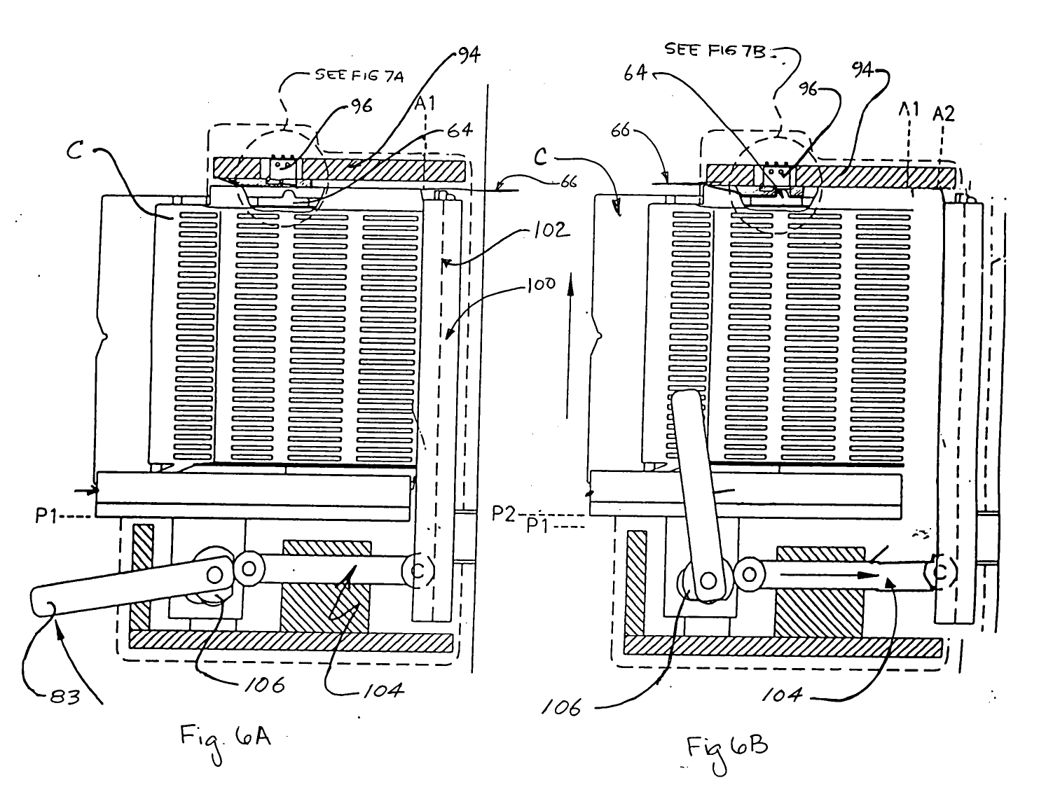

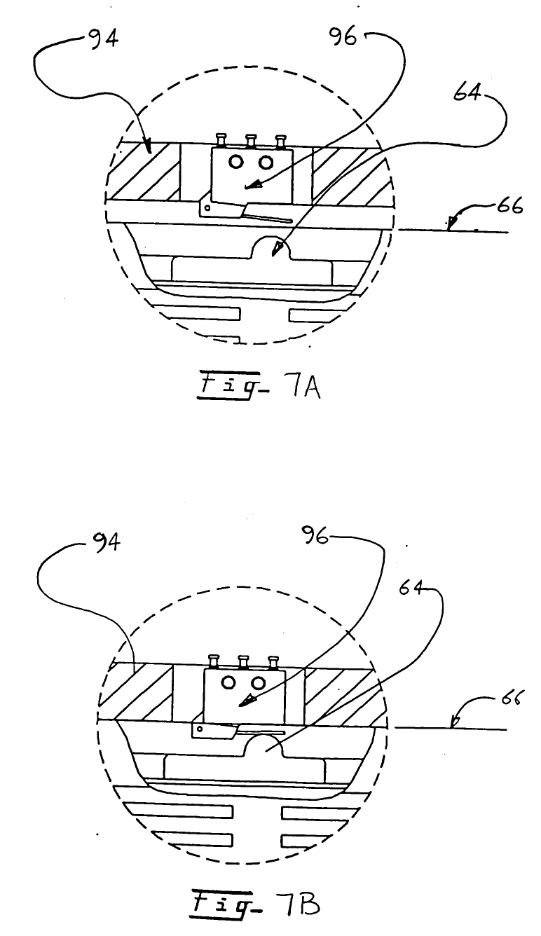

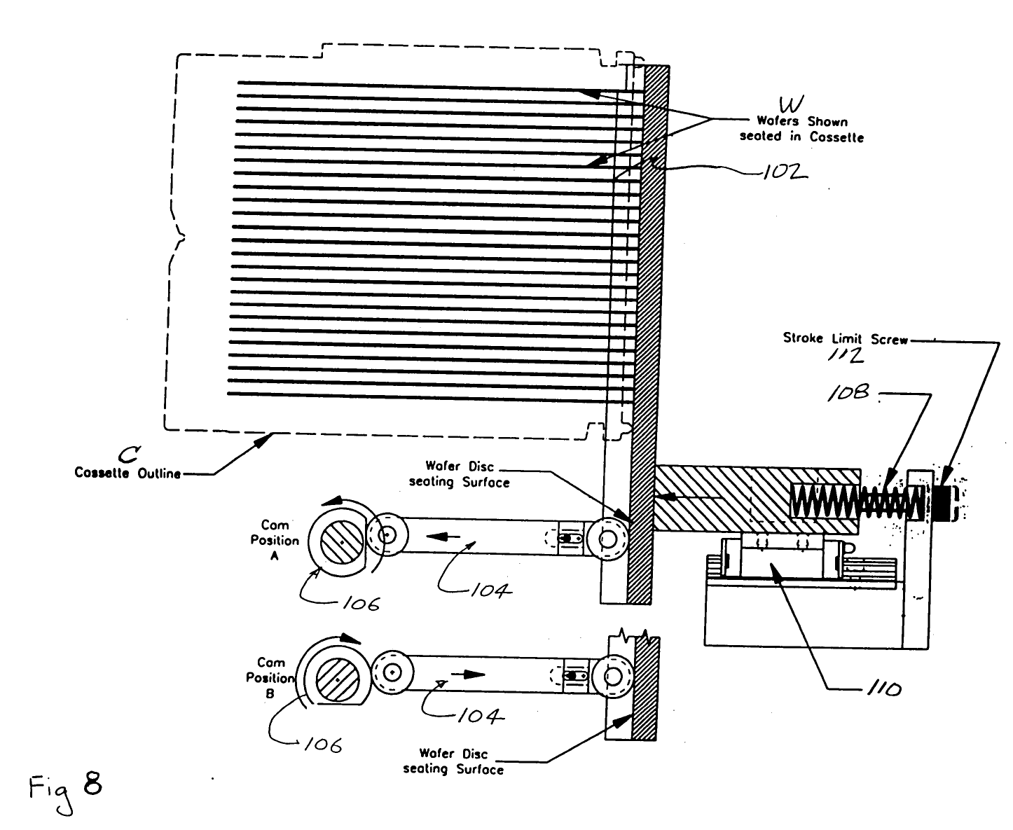

Cassette holder comprises a housing 82 having sides 84 and 86, and a base 88. Base 88 has a pair of runners 90 and 92 (FIGS. 7A and 7B) which complement the bottom shape of cassette C so that cassette C can slide in place in a longitudinal direction into cassette holder. Cassette C has a so called H-Bar 64 which aligns with the top plate 94 of cassette holder. When cassette C is locked in place, H-Bar 64 engages switch 96 (FIGS. 6A, 6B) to condition the apparatus and system 10 for transferring wafers W into shipping container J in a manner described hereafter.

A wafer-seating plate 100 having a curved front face 102 complementing the curvature of wafers W is engaged by wafers W when the cassette C is positioned in place in the cassette holder. The function of the wafer-seating plate 100 is to ensure that all of wafers W are fully seated in cassette pockets 78 so that the pickup arm 34 engages the back side surface of each wafer 12 in the same relative position thereby properly aligning the wafers W when they are transferred to the shipping container J.

When the cassette C is in place in the manner described above, the handle 83 is rotated from its horizontal rest position as shown in FIG. 6A to the position shown in FIG. 6B. Through a linkage 104 and cam 106 arrangement, the wafer-seating plate 100 moves forwardly so that there is a predetermined clearance between the front face of seating plate 100 and wafer W to permit transfer of wafers W in a manner to be described. As shown in FIG. 6A, the wafer-seating plate 100 is normally biased to a forward limit position (cam position A, FIG. 8) by a pair of compression springs 108. A slide bearing 110 supports the wafer-seating plate 100 so that it moves in a truly horizontal plane and does not cock during activation between cam position A and cam position B thereby seating all of wafers W in a uniform fashion. The actuation of the handle 83 raises cassette C so that the H-Bar 64 engages and locks in place with the top plate 94 of cassette holder 82. When cassette C is fully locked in place, switch 96 conditions the system for operation and feed and transfer of wafers W from the cassette C to the transfer station 16. The clearance between the wafers W and the wafer-seating plate 100 ensures incremental vertical displacement of the cassette C during the transfer cycle in a manner to be described in more detail hereafter.

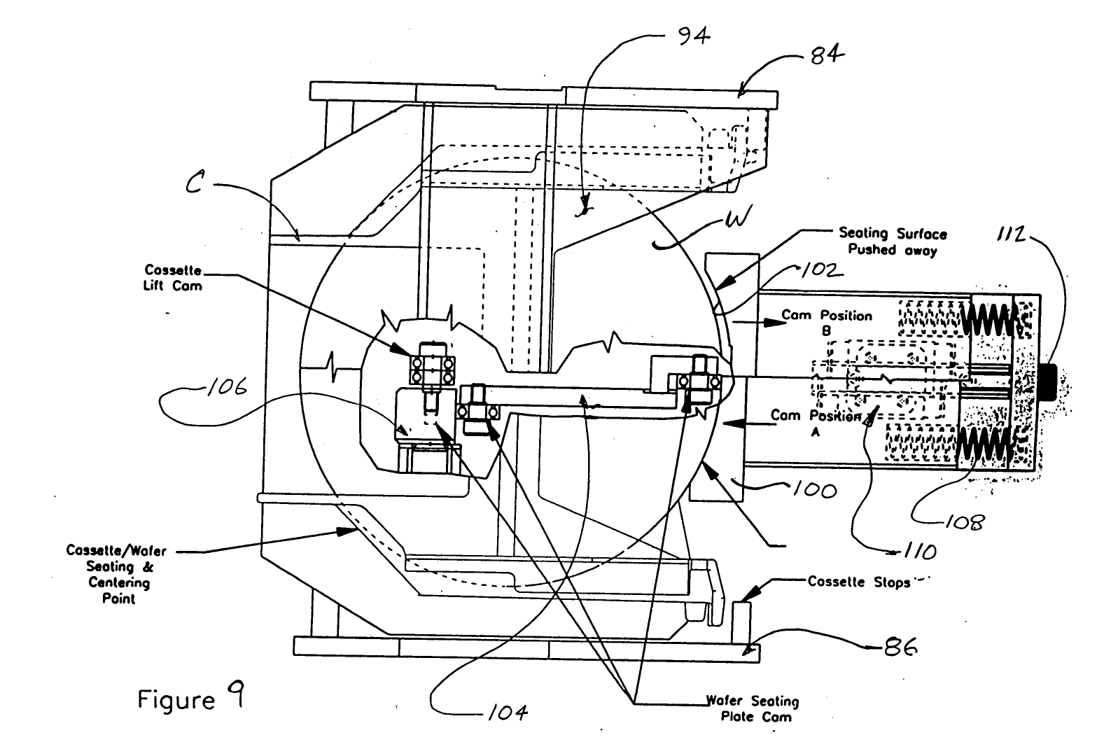

FIG. 8 illustrate the wafer-seating plate 100 when the cassette C is loaded and when the lift handle 88 is rotated. FIG. 9 is a cut-away to show a top view of the cam linkage 104. The wafer-seating plate 100 is split along the center showing the portion with respect to the wafer W and cassette C with cam 106 in position A and B. When at position B, the cassette C is raised and the H-Bar 64 is deflected as shown in FIG. 9. FIG. 8 illustrates the linear motion achieved upon moving cam 106 from position A to B and details the opposing linear compression spring 108 stroke limit screw 112 and linear slide bearing 110 arrangement.

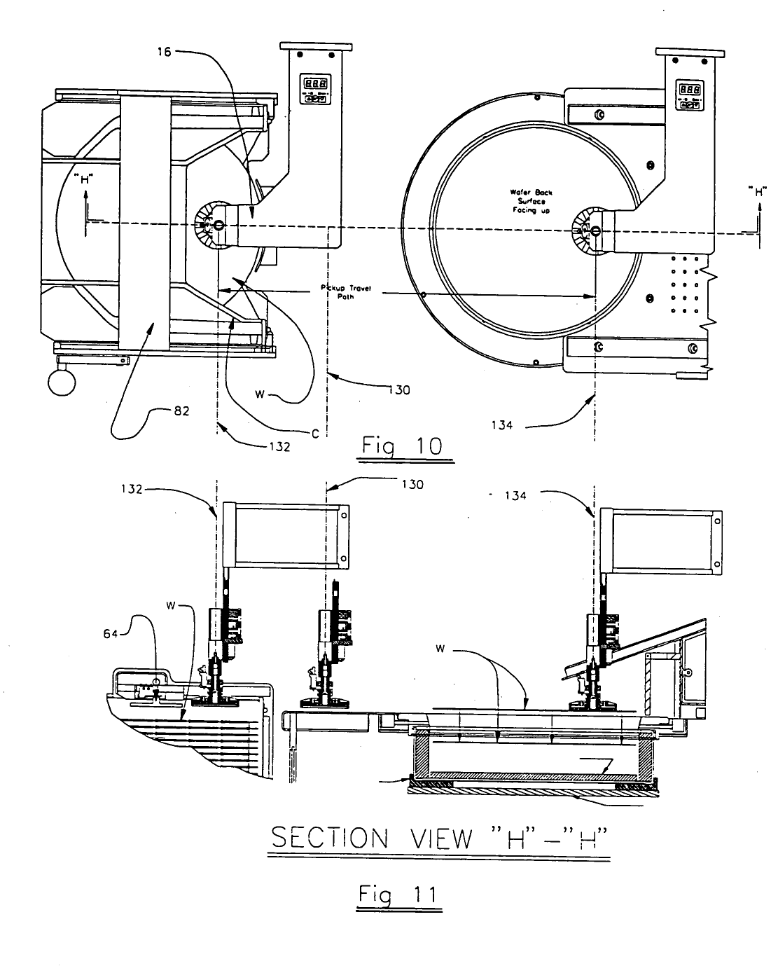

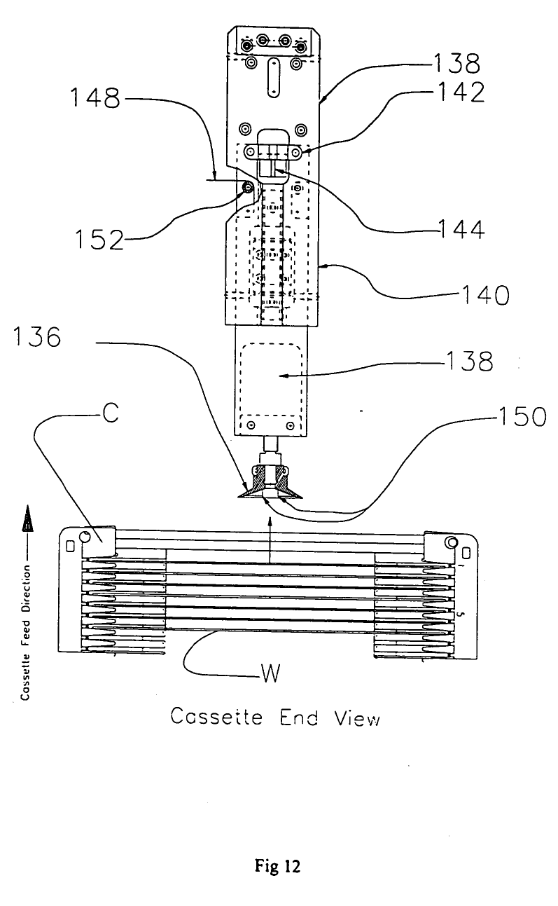

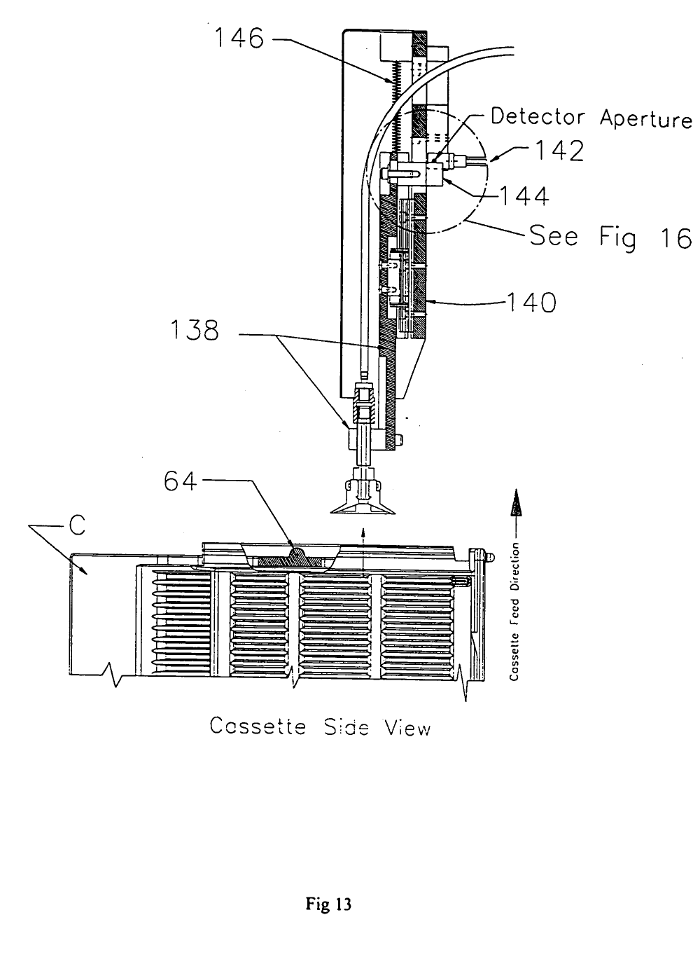

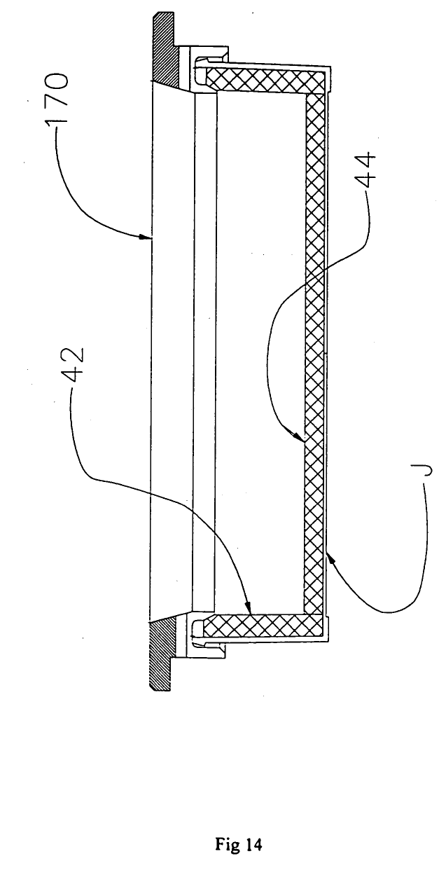

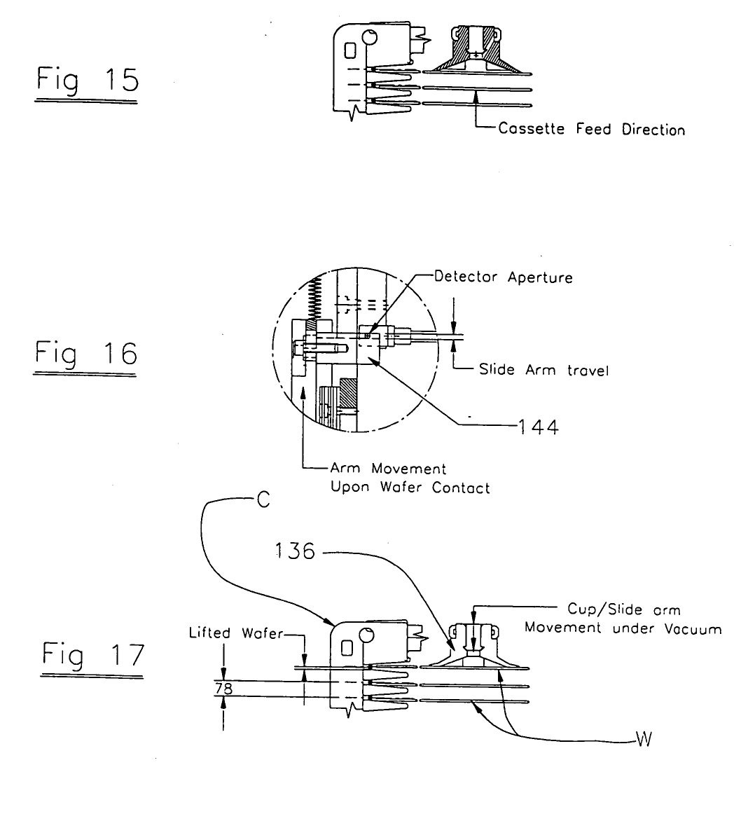

Consider now the pick up transfer station 16 of FIGS. 1 and 2 and with reference to FIGS. 10, 11 and 12. When switch 96 in cassette holder 82 is activated by H-Bar 64 verifying that cassette C has been loaded in correct orientation, pick up arm 34 is enabled for automatically transferring wafers W from cassette C to shipping container station 18. FIG. 11 is a side cutaway view wherein the pickup arm 34 transfers wafer W to wafer release position 134. FIGS. 11 and 12, are side and front elevation views of transfer pickup arm assembly 34 and cassette C. The portion of cassette holder 70 that secures and registers the H-Bar 64 has been hidden from this figure for explanation of the wafer pickup sequence. The pickup/transfer arm assembly 34 consists of a vacuum cup 136, slide arm 138, slide base 140, gap sensor 142, interrupt flag 144, counterbalance extension springs 146, and two-screw stops 148. The slide arm 138 is shown in a starting position where the slide arm 138 is downward and arrested on two-screw heads 148 and stop surfaces 148. The two counter balance springs 146 add resistance in the opposite direction to reduce the effective weight of the slide arm assembly 140 that will contact the wafer W. FIG. 12 best illustrates the gap sensor 142 and interrupt flag 144 relationship with the slide arm 140 in the starting position. The distance between the sensor 142 and the flag 144 allow for detection of contact with the wafer W. The amount of slide arm 138 movement can be varied by adjusting the distance away from the sensing point. For compliant type vacuum cups 136, this distance allows the cup to collapse without pulling the wafer W upward against the cassette C top side support grooves. As illustrated in FIG. 15, the vacuum cup 136 illustration identifies “cup support ribs” 150. These ribs 150 are stops within the vacuum cup 136 which limit the amount of compliance on vacuum cup 136 when vacuum is drawn. FIG. 15 shows the vacuum cup 136 making initial contact with the wafer W. The wafer 12 continues being raised until the flag 144 interrupts the sensor 142 within the gap distance shown in FIG. 15. Once the sensor 142 is blocked, cassette C motion is stopped and vacuum is turned on to the vacuum cup 136. As vacuum builds up, the cup 136 begins to collapse. This collapsing motion allows the slide arm 58 to move downward until the stop surfaces 148 are engaged by the screw head 152. Then the balance springs 146 lift the wafer W off the bottom side guides as shown in FIG. 16. The last motion is when the cassette C is lowered a programmed amount to center the wafer within the cassette support slots and the wafer is pulled out.

Consider now a typical cycle of operation with the parts in the position shown in FIGS. 10 and 11. The pickup transfer arm 34 is moved from a position overlying the container J to the wafer W and then the cassette C is raised so that the top wafer W engages the vacuum cup 136 and displaces the slide arm 58 a predetermined distance as determined by gap sensor 142. This initiates the vacuum which causes the vacuum cup 136 to flatten and tend to displace a wafer W upwardly a predetermined small distance. However, the slide arm 58 can return to its home position and in this position, the wafer W is centered in its pocket 32 to avoid any biasing in the grooves of the cassette C which may damage the wafer W. When all of the wafers W in a given cassette C have been transferred from the cassette C to jar or container J, the control panel then signals the operator to replace the empty cassette C with another full one. The system 10 can be set to transfer selected numbers of wafers W for an automatic cycle of operation.

Consider now briefly part of an operational cycle and assume that the pickup arm overlies the wafer W and the system is ready to initiate a transfer cycle. In position 132 of pickup arm 34, a cassette drive motor elevates the cassette holder 82 and when the top wafer W engages the suction cup 136, the sensor flag 144 activates the gap sensor 142 which signals the cassette motor to stop. Simultaneously, the vacuum cycle is activated. The vacuum causes the suction cup 136 to comply. The arrangement just described including the flag 144 sensor 142 and limited range of travel of a slide arm 138 in slide base 140 ensures that wafers W are not damaged or are biased in the cassette pockets 78 during a transfer cycle. The pickup assembly further includes counter-balancing springs 180 extending from a projection on slide base 140 to the slide arm 138 as shown in FIG. 12. This arrangement minimizes load on the wafers W and on the suction cup 136 when the cassette C is raised in the manner described above wherein the top wafer is engaged initially by the suction cup 136 again in the manner described above.

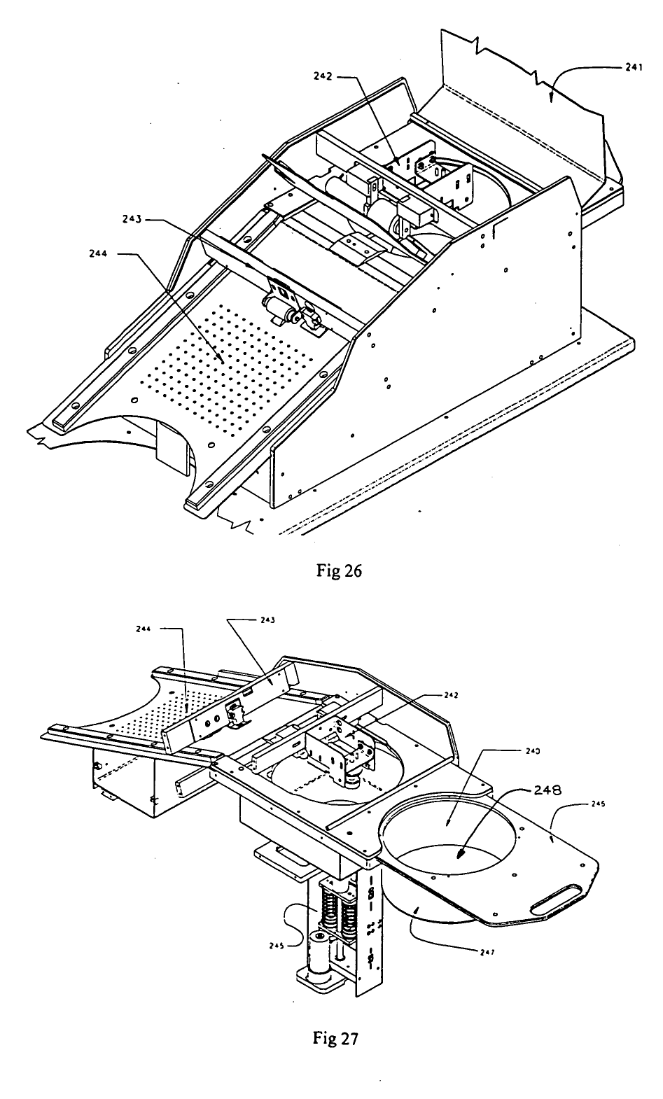

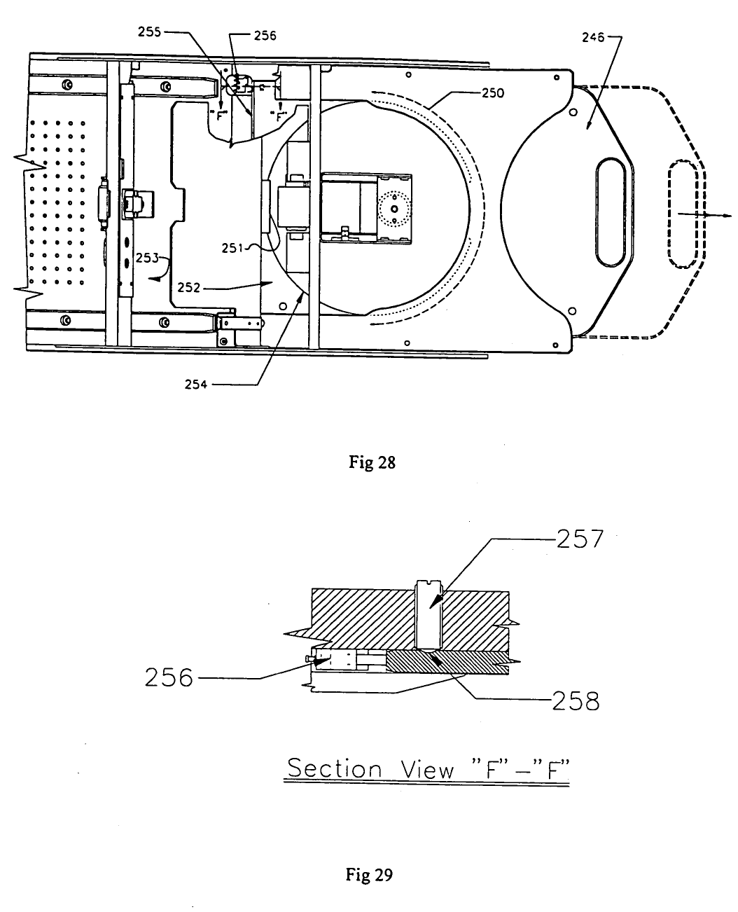

Considering now the Interleaf station 22, and referring to FIGS. 26 and 27, perspective views of the Interleaf feed mechanism are shown. Disc-like interleafs I made of a tissue paper product are stacked in Interleaf holder 240 (shown in an op load position), automatically released and interspersed one at a time between wafers(W). In FIG. 26, the Interleaf cover 241 is shown in an open position exposing the paper buckle and release mechanism 242, Interleaf queue and release station 243, air cushion chute 244, and Interleaf lift mechanism 245. Interleaf holder 240 is an elongated generally rectangular slide drawer 246 having an open bottom depending-cylindrical container 247. interleafs I are stacked on top of a vertically movable lifter pad 248 which is attached to the upper end of lifter adjustment screw 249 and projects into the open bottom of cylindrical container 247. lnterleafs I are held in place in the cylindrical container 247 of Interleaf holder 240 by a semi-circular back edge retainer 250 of FIG. 28 which projects slightly beyond the opening of cylindrical container 247 to engage an annular portion of the top Interleaf I. A peel blade 251 having an entrance and exit ramps 252 and 253 respectively extends over the Interleaf opening at approximately from the rim 254 to hold the interleafs I in place in the manner shown in FIG. 28.

When the slide drawer 246 is seated, as shown in FIG. 28, Slide drawer front edge 255 depresses switch 256 and ball plunger 257 extends in slide drawer detent grooves 258 seating slide drawer 2, and preparing the system 10 for sequential operation.

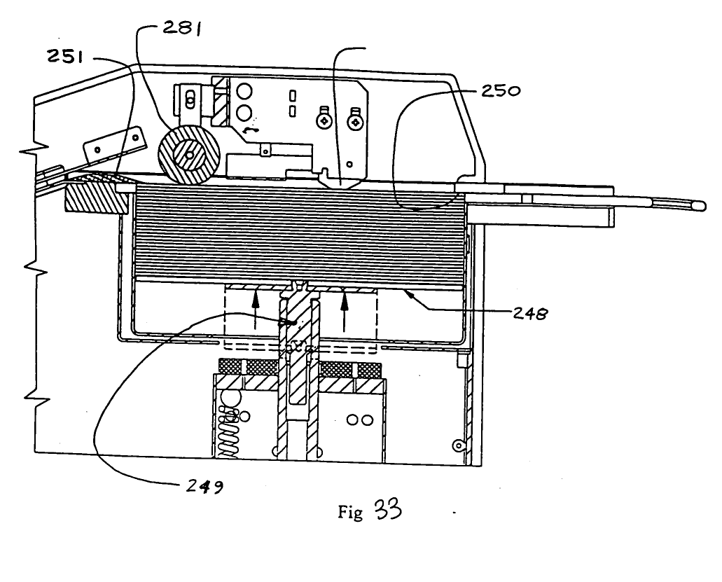

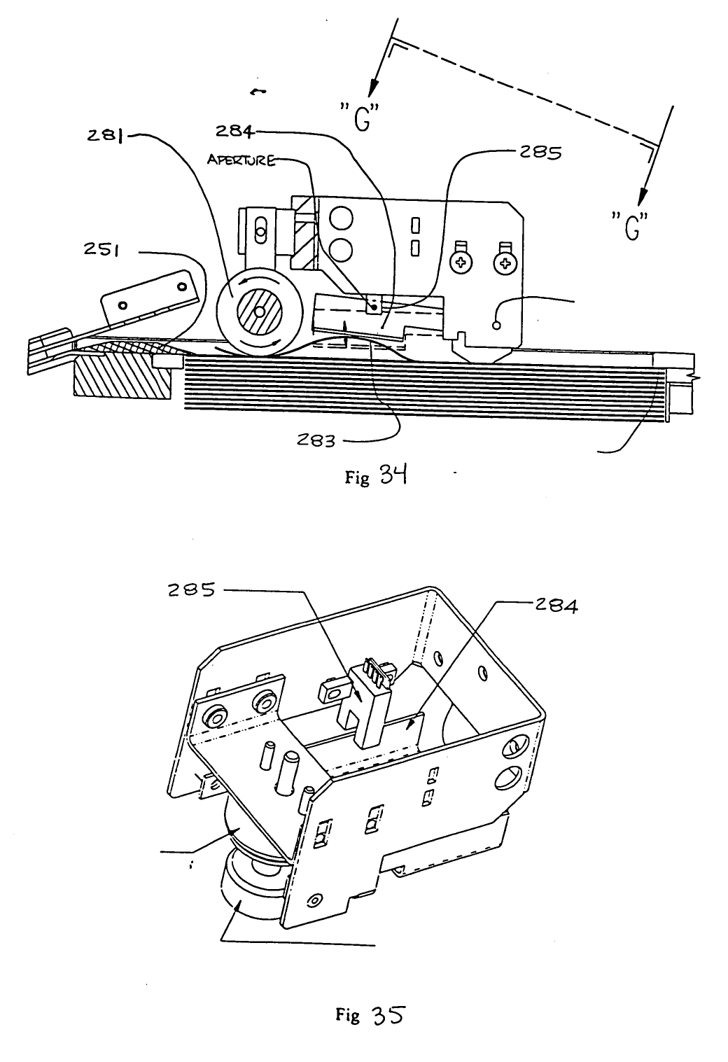

With slide drawer 246 in place, the feed sequence begins with the Interleaf lift mechanism 245 raising the interleafs I up to peel blade 251 and back edge retainer 250 applying a constant but controlled force as shown in FIG. 33. The distance between pre-load springs 259 and upper support angle 260 and lower support angle 261 achieve this constant force as shown in FIG. 33. Both support angles 260 and 261 are attached to two linear rail bearing slide blocks 262 and 263.Both upper support angle 260 and lower support angle 261 and bearing blocks 262 and 263 have the pre-load gap/distance maintained by threaded rod and pre-load adjustment nut 265. The threaded rod' 264 is attached to a threaded spring post 266 and locked with nut 267. The opposite end passes through a clearance hole in spring post 268 and through lower support angle 261. The pre-load adjustment 265 works against pre-load springs 259 to maintain a predetermined distance between upper support angle 260 and lower support angle 261. The pre-load adjustment nut 265 has a tapered surface which makes contact with a pre-load sense switch that indicates nut 265 is seated against lower support angle 261.

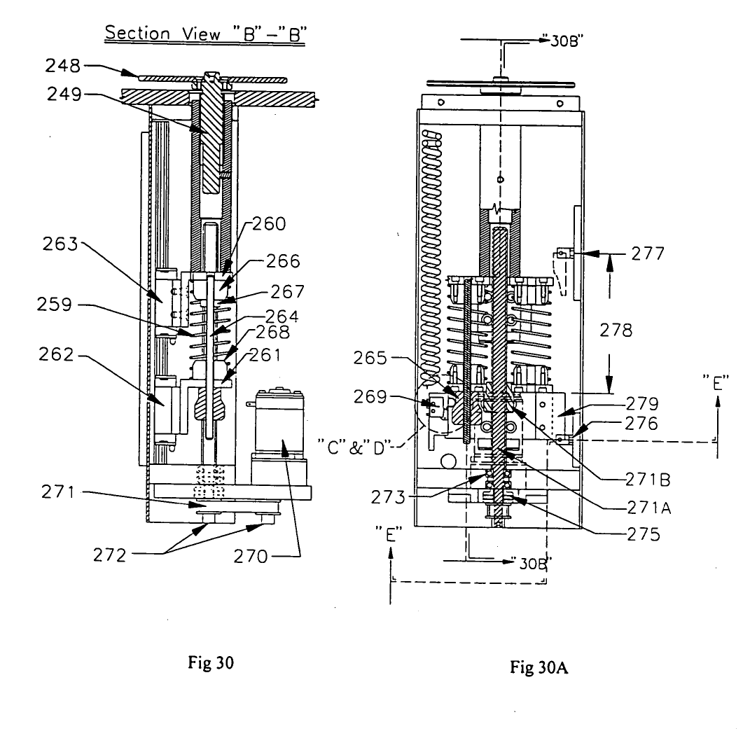

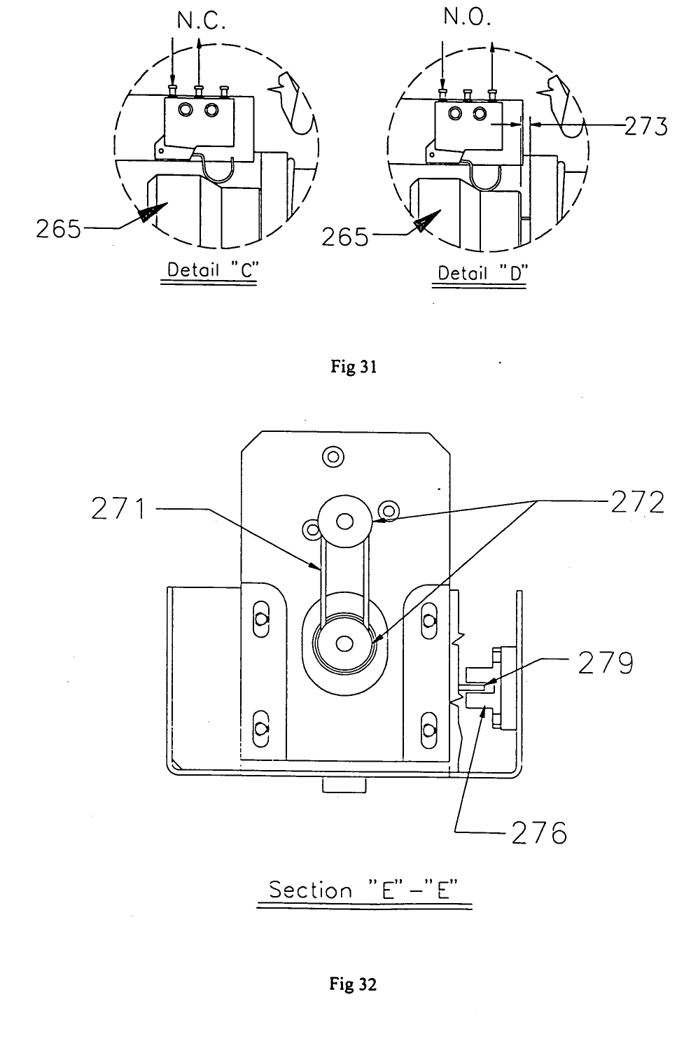

During the Interleaf lift cycle, the force of the pre-load spring 265 will be exceeded causing upper support angle 260 and bearing block 263 to move toward opposing bearing block 262. This movement causes pre-load nut 265 to move away from lower angle 261. This small movement causes switch 269 to change state deactivating pre-load drive motor 270 which stops drive belt 271 and pulleys 272 This small is illustrated on FIG. 31 wherein detail “IC” shows switch 269 in a normally open condition on tapered surface of adjustment nut 265 which indicates no pre-load sensed and detail “D” shows switch 269 off taper of adjustment nut 265 in a normally closed condition which indicates a pre-load is sensed. Detail “D” also shows the gap 273 within which the pre-load switch 269 operates. Section E-E of FIG. 32 is a bottom view of the pulleys 272 and drive belt 271 that drive lead screw 271A with attached lead screw nut 2713. Lifting of lifter pad 248 by lead screw 271A is achieved through the drive belt 271 and pulleys 272. Lead screw 271A is supported by two angular contact bearings 273 and retained through a mounting block 274 via a bearing take up nut 275. On activation of pre-load drive motor 270, lead screw 271A through drive belt 271 and pulleys 272 and motor 270 cause the nut 275 to move up/down depending on state of switch 269. Lower stroke limit sensor 276 and upper stroke limit sensor 277 control and limit the extent of Interleaf lift travel 278. Stroke limit sensors are triggered when the sensor flag 279 interrupts a light beam. This i illustrated in FIG. 30A with the flag 279 shown at the lower stroke limit position. Section E-E of FIG. 32 shows a view of flag 279 passing through the sensor. During the upward cycle of raising and pre-loading interleafs, the pre-load switch 269 is activated and motor 270 stops until enough Interleaf sheets have been stripped from the stack to reactivate switch 269 and turn on motor 270. This sequence repeats until the upper stroke limit sensor 277 is blocked by flag 279. When this upper limit has been reached and switch 269 activates indicating no more pre-load is present, the motor is reversed until the sensor flag 279 returns to the starting lower limit stroke 276 position.

Considering now the interleaf station 22, and referring to FIGS. 26 and 27, perspective views of the interleaf feed mechanism are shown. Disc-like interleafs I made of a tissue paper product are stacked in interleaf holder 240 (shown in an open load position), automatically released and interspersed one at a time between wafers(W). In FIG. 26, the interleaf cover 241 is shown in an open position exposing the paper buckle and release mechanism 242, interleaf queue and release station 243, air cushion chute 244, and interleaf lift mechanism 245. Interleaf holder 240 is an elongated generally rectangular slide drawer 246 having an open bottom depending cylindrical container 247. Interleafs I are stacked on top of a vertically movable lifter pad 248 which is attached to the upper end of lifter adjustment screw 249 and projects into the open bottom of cylindrical container 247. Interleafs I are held in place in the cylindrical container 247 of interleaf holder 240 by a semi-circular back edge retainer 250 of FIG. 28 which projects slightly beyond the opening of cylindrical container 247 to engage an annular portion of the top interleaf I. A peel blade 251 having an entrance and exit ramps 252 and 253 respectively extends over the interleaf opening at approximately from the rim 254 to hold the interleafs I in place in the manner shown in FIG. 28.When the slide drawer 246 is seated, as shown in FIG. 28, Slide drawer front edge 255 depresses switch 256 and ball plunger 257 extends in slide drawer detent grooves 258 seating slide drawer 246 and preparing the system 10 for sequential operation. With slide drawer 246 in place, the feed sequence begins with the interleaf lift mechanism 245 raising the interleafs I up to peel blade 251 and back edge retainer 250 applying a constant but controlled force as shown in FIG. 33. The distance between pre-load springs 259 and upper support angle 260 and lower support angle 261 achieve this constant force as shown in FIG. 33. Both support angles 260 and 261 are attached to two linear rail bearing slide blocks 262 and 263. Both upper support angle 260 and lower support angle 261 and bearing blocks 262 and 263 have the pre-load gap/distance maintained by threaded rod and pre-load adjustment nut 265. The threaded rod 264 is attached to a threaded spring post 266 and locked with nut 267. The opposite end passes through a clearance hole in spring post 268 and through lower support angle 261.

The pre-load adjustment nut 265 works against pre-load springs 259 to maintain a predetermined distance between upper support angle 260 and lower support angle 261. The pre-load adjustment nut 265 has a tapered surface which makes contact with a pre-load sense switch that indicates nut 265 is seated against lower support angle 261. During the interleaf lift cycle, the force of the pre-load spring 265 will be exceeded causing upper support angle 260 and bearing block 263 to move toward opposing bearing block 262. This movement causes pre-load nut 265 to move away from lower angle 261. This small movement causes switch 269 to change state deactivating pre-load drive motor 270 which stops drive belt 271 and pulleys 272. This small is illustrated on FIG. 31 wherein detail “C” shows switch 269 in a normally open condition on tapered surface of adjustment nut 265 which indicates no pre-load sensed and detail “D” shows switch 269 off taper of adjustment nut 265 in a normally closed condition which indicates a pre-load is sensed. Detail “D” also shows the gap 273 within which the pre-load switch 269 operates. Section E-E of FIG. 32 is a bottom view of the pulleys 272 and drive belt 271 that drive lead screw 271A with attached lead screw nut 271B. Lifting of lifter pad 248 by lead screw 271A is achieved through the drive belt 271 and pulleys 272. Lead screw 271A is supported by two angular contact bearings 273 and retained through a mounting block 274 via a bearing take up nut 275. On activation of pre-load drive motor 270, lead screw 271A through drive belt 271 and pulleys 272 and motor 270 cause the nut 275 to move up/down depending on state of switch 269. Lower stroke limit sensor 276 and upper stroke limit sensor 277 control and limit the extent of interleaf lift travel 278.

Stroke limit sensors are triggered when the sensor flag 279 interrupts a light beam. This is illustrated in FIG. 30A with the flag 279 shown at the lower stroke limit position. Section E-E of FIG. 32 shows a view of flag 279 passing through the sensor. During the upward cycle of raising and pre-loading interleafs, the pre-load switch 269 is activated and motor 270 stops until enough interleaf sheets have been stripped from the stack to reactivate switch 269 and turn on motor 270. This sequence repeats until the upper stroke limit sensor 277 is blocked by flag 279. When this upper limit has been reached and switch 269 activates indicating no more pre-load is present, the motor is reversed until the sensor flag 279 returns to the starting lower limit stroke 276 position.

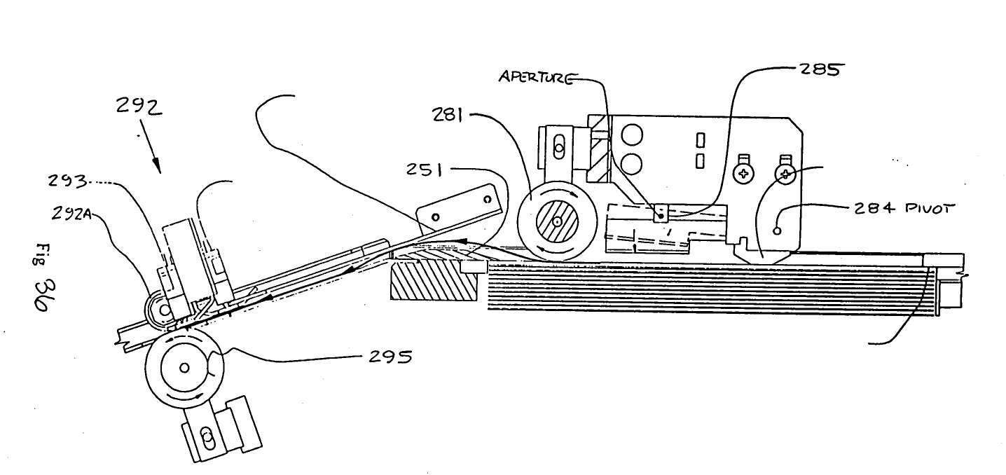

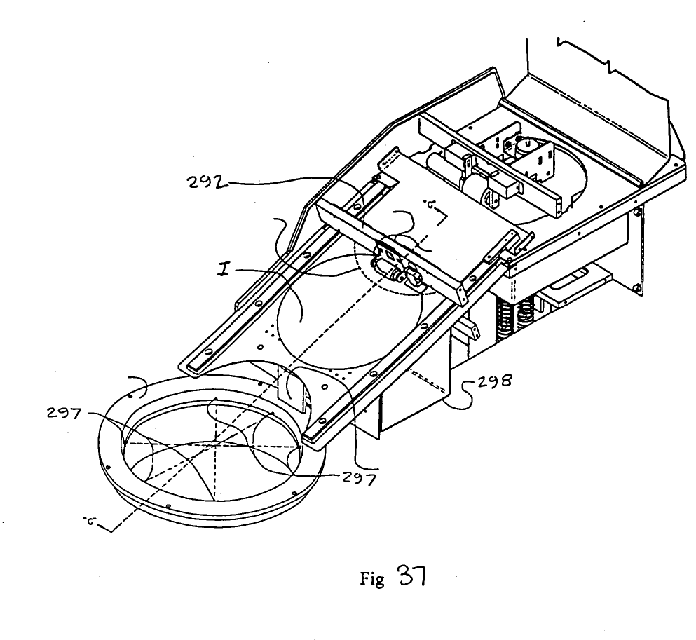

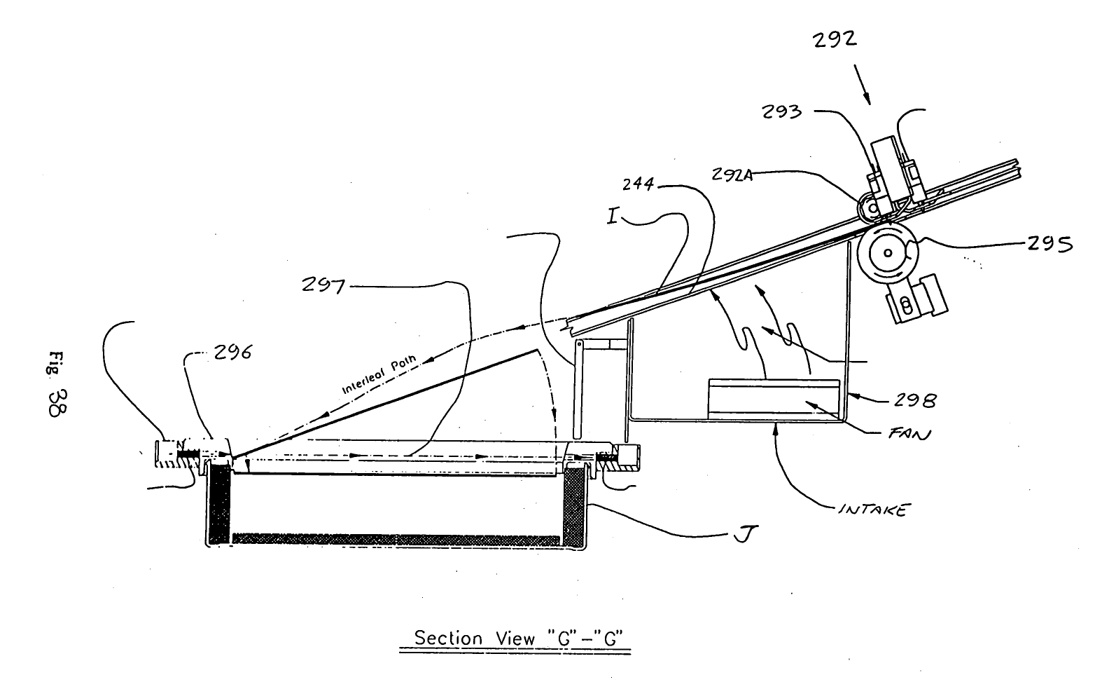

Having positioned the interleaf stack for releasing single interleaf discs into the shipping container J, pre-load switch 269 activates pre-load drive motor 270 thereby causing lifter pad 248 to move upward through opening in the interleaf holder 240 to engage metal disc 280. The interleaf stack is forced against and stopped by the peel blade 251 and back edge retainer 250. Pre-load switch 269 now removes power from pre-load drive motor 270 readying interleafs for stripping one at a time while incremental pressure is maintained on the stack. Interleaf disc separation begins by activating separator motor 281 that drives the buckle/feed tire in a counter clockwise rotation pulling the front portion of the top interleaf to be pulled backwards from under peel blade 251 and causing the front portion of the top interleaf disc to bow or buckle upward 283 making contact with a light weight buckle paddle 284 pivoting it upward around its pivot point thereby activating sensor 285 mounted in housing 287 confirming interleaf has been released from under peel blade 251. Adjustment of sensor 285 can allow more or less buckling to occur. View G-G of FIG. 35 is an isometric more clearly showing sensor 285 and buckle paddle 284. Having released the top interleaf from under peel blade 251, power to separator motor 281 is reversed causing buckle/feed tire to rotate clockwise pushing the interleaf forward and up over knife edge of peel blade 251 and under interleaf deflector 290 that guides the interleaf towards the queue and release station 292 and idler wheel 292A as shown in FIGS. 36 and 37. When the front edge of the interleaf is detected by queue sensor 293 causing power to separator motor 281 to be turned off releasing the back portion of the interleaf so that the interleaf may continue its forward progress. FIG. 37 illustrates the relationship.

The last part of the sequence is the release of the interleaf to the shipping container. First, a fan in fan enclosure 298 underneath the air chute 244 is turned on to provide an air cushion underneath the interleaf. The interleaf release/stage wheel 295 is reactivated releasing the interleaf and causing the interleaf to float down the inclined air cushion chute 244 surface toward a shipping container. The funnel ring 296 is tapered upward to form a funnel-like entrance to the shipping container to provide more clearance for the interleaf to enter. Three emitter/detector pairs 297 on the funnel ring form a light curtain sensing the passage of an interleaf. When any of the sensor pairs 297 detects an interleaf, the interleaf release/stage wheel 295 is turned off. These sensors 297 continue to be monitored until all sensors are unblocked indicating the interleaf has passed through into the shipping container. FIG. 38 is a cutaway view taken along line G-G of FIG. 37 showing the progress of an interleaf as it passes from the queue and release station 292 down air cushion chute 244 and into a shipping container. This sequence continues all interleafs are interspersed between wafers.

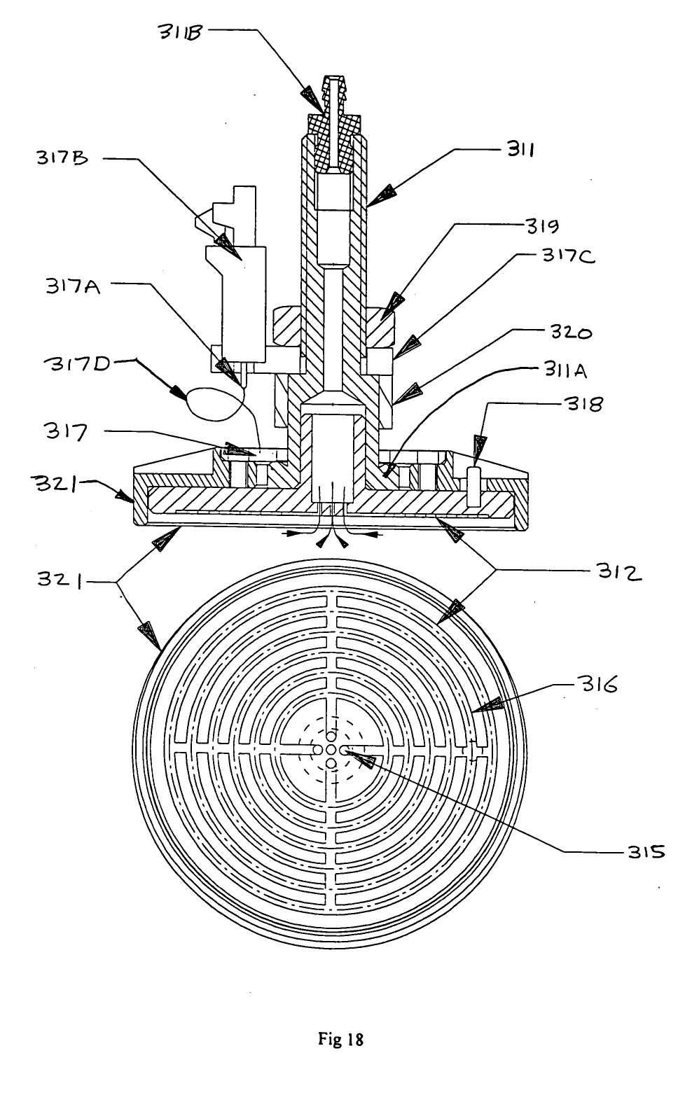

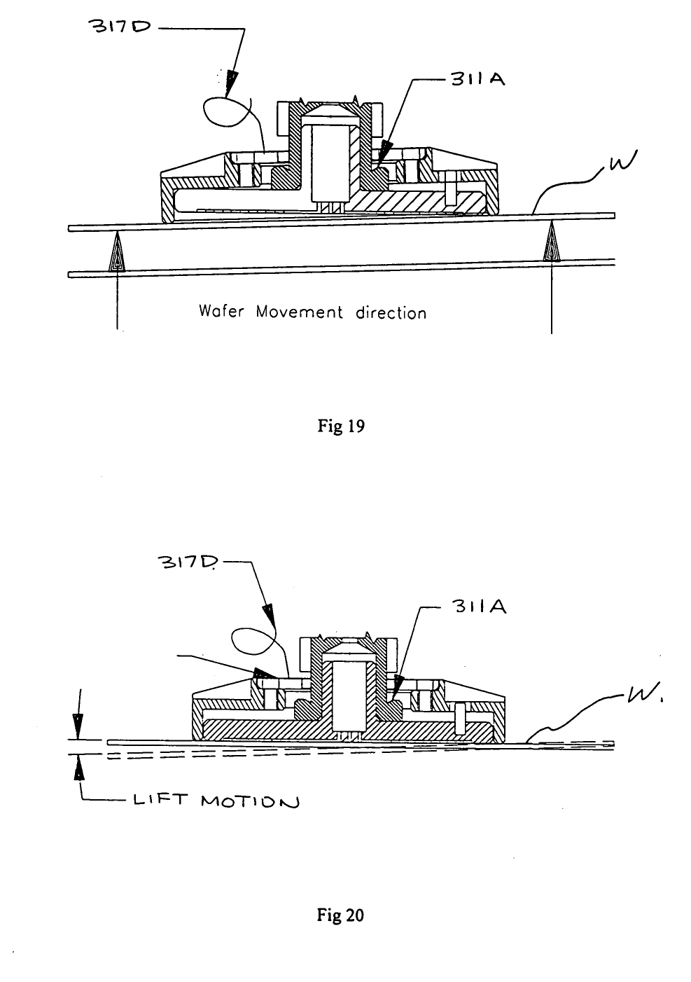

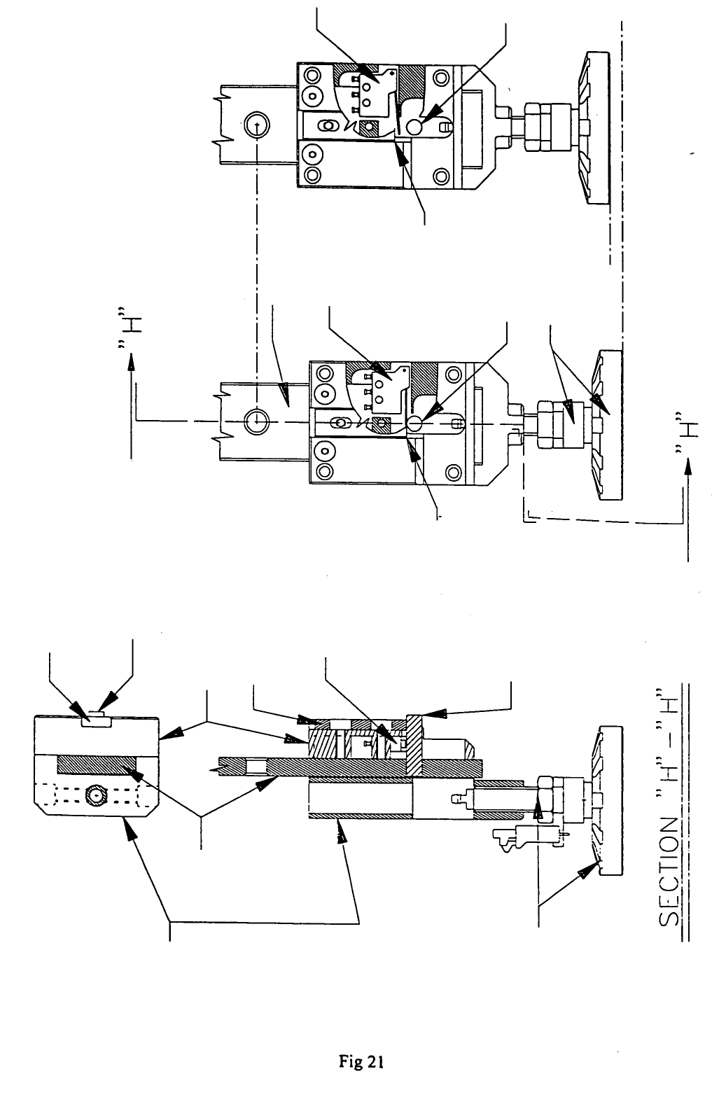

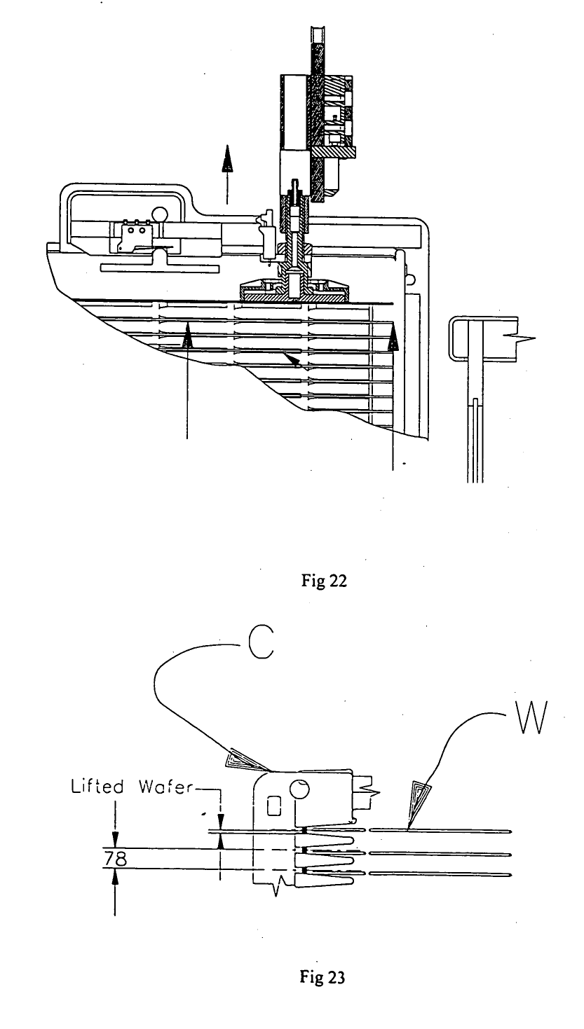

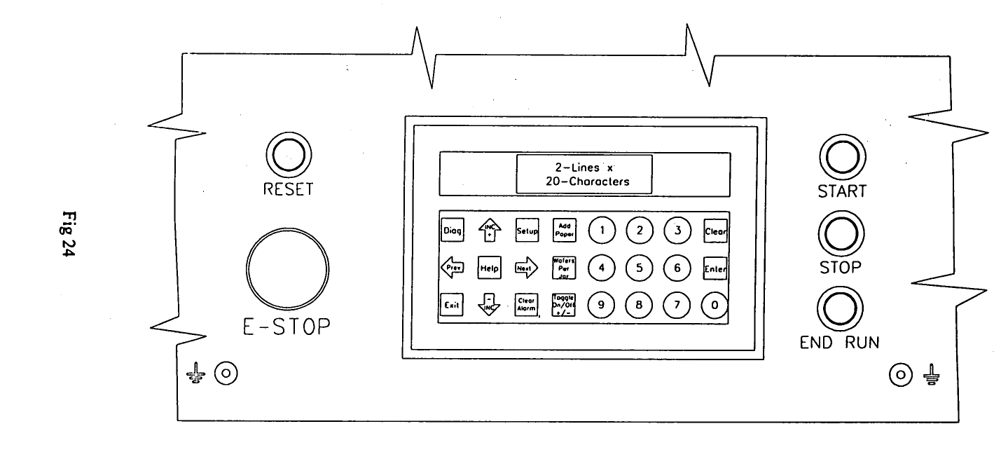

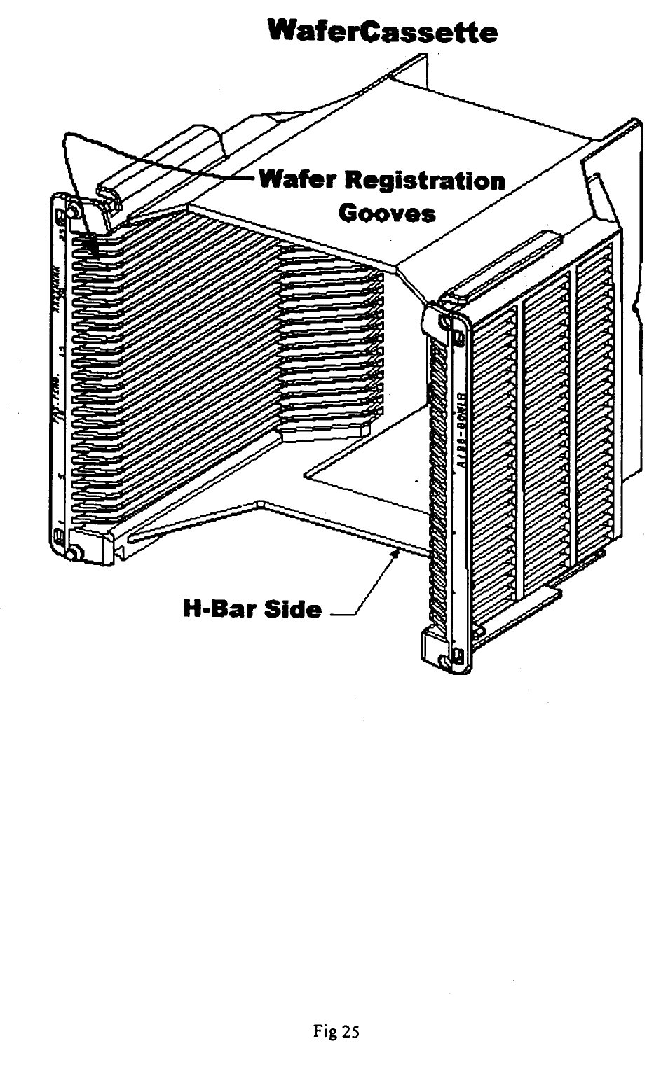

In a second embodiment, the vacuum pickup cup incorporates novel features of construction and arrangement to obviate potential non-alignment issues. The potential for both the wafer pickup surface and cup pickup surface being out of parallel is a normal condition. Though this parallel alignment error may not be large, it can be enough to prevent vacuum to be pulled. Referring now to FIG. 18, the pickup cup generally designated 310 consists of a threaded support post 311 which extends downwardly to the rigid pickup cup 312 where if flanges out as at 311A to form one side of an electrical contact 313. The flanged out section 311A has a hollow bore to allow a press fit of rigid cup 312. A port 314 through the center of support post 311 allows a vacuum to be pulled through rigid cup 312 and the small holes 315 that feed a pattern of circular grooves 316 which provide sufficient area to securely hold the wafer W during transport from the cassette C to the shipping containers J.

A floating cup ring 321 surrounds and slips over rigid cup 312 and has a recess in the upper surface of the flange to secure the upper contact 317. Lead wire 317A is soldered to contact 317 and terminates in and is attached with connector mount 317C a two-pin connector 317A and locked to threaded post 311 with lock nut 319. Upper contact 317, therefore, forms a normally closed switch. To prevent floating cup 321 from rotating and severing contact wire 317D, an anti-rotate pin 318 is provided eliminating rotation between parts. To assure anti-rotate pin 318 cannot dislodge, a plastic stroke limiter sleeve 320 is positioned above and returned via a press fit onto support post 311. The floating cup ring 321 has a periphery extending outer depending flange 316A which projects a predetermined distance D below a plane P-P through the bottom face 312A of cup ring when the cup ring 316 is fully seated as shown in FIG. 18. Accordingly, when the vacuum assembly 310 is positioned to pick up a wafer W, the flange 316A first engages the wafer surface and is displaced relative to the cup 321. The contacts are opened to initiate activation of the vacuum.

What is claimed is:

1. A method for packaging wafers having a bottom side and a top circuit side in containers comprising the steps of;
placing a cassette having a plurality of pockets for wafers with the back side facing upwardly,
transferring the top wafer in the cassette by means of a vacuum suction mechanism which centers the top wafer in the cassette pocket upon initial engagement and
transferring and discharging the wafer to a container located at a container station and feeding interleafs in timed relation to the wafer feed so that an interleaf is positioned between each wafer loaded in a container.

2. A method as claimed in claim 1 including the step of centering the wafer in the pocket of the cassette before withdrawing it from the pocket by the vacuum suction mechanism.

3. A method as claimed in claim 1 including the step of levitating the interleaf as it traverses a chute guiding the interleaf from the interleaf station to the container.

4. A method as claimed in claim 1 including the step of maintaining a predetermined stacking pressure on the interleafs at the interleaf transfer station.

5. A method for packaging wafers having a bottom side and a top circuit side in containers comprising the steps of;
placing a cassette having a plurality of pockets for wafers with the back side facing upwardly,
transferring the top wafer in the cassette by means of a vacuum suction mechanism which centers the top wafer in the cassette pocket upon initial engagement,
transferring and discharging the wafer to a container located at a container station and feeding interleafs in timed relation to the wafer feed so that an interleaf is positioned between each wafer loaded in a jar and
activating the vacuum suction mechanism linearly only between opposing limit positions to achieve a direct transfer of wafers from a wafer loading station to the container station.

6. In a system for packing wafers in a jar compromising a first wafer station wherein a plurality of wafers are mounted in pockets of a cassette with the circuit side of the wafer facing downwardly in the cassette, a suction pick up mechanism for transferring one wafer at a time from the wafer loaded station to a jar loading station, means for advancing the cassette as wafers are removed and said suction pick up positioning the wafers centrally in the pocket before transfer and means for feeding an interleaf in predetermined timed sequence with the wafer transfer to position an interleaf between each wafer delivered to the jar at the jar station.

7. Apparatus for delivering disc like interleafs one at a time comprising an interleaf holder, a peel blade and a back support overlying an edge of holder, means for maintaining a predetermined pressure of the interleaf stack against the peel blade and back support as interleafs are removed from the holder, a buckle feed roller overlying the stack of interleafs including means for rotating the roller in one direction to release the front edge of the top most interleaf from the peel blade so that the front edge can engage over the ramp of the peel blade means for rotating the roller in the opposite angular direction to release the rear edge of the interleaf held by the back support to advance the upper interleaf to a discharge station.

8. A system is claimed in claim 6 wherein the vacuum suction mechanism comprises a rigid disc-like cup member having a plurality of channels on its outer face which communicate through holes with a vacuum source and an outer floating cup ring, tiltably mounted over the rigid pickup cup including mean for preventing relative rotation of said floating cup ring and pickup cup, said cup ring having an outer peripheral wall which in the seated position extends below the plane of the bottom face of the rigid pickup cup member to provide a compliant function when the suction mechanism is positioned to pick up a wafer at the wafer loading station.

9. A system is claimed in claim 8 including cup and support post contact means which are normally engaged when the outer floating cup ring is seated on the rigid pickup cup and disengage when the rim of the rigid pickup floating cup engages a wafer to initiate activation of the vacuum system.

10. A system is claimed in claim 8 wherein the axial displacement distance of the rigid pickup cup in the outer floating cup ring is such that the wafers are relatively centered in the pocket upon disengagement of the contacts to initiate activation of the vacuum displacing the rigid cup in the floating cup ring.

11. A vacuum suction mechanism comprising a rigid disc-like cup member having a plurality of channels on its outer face which communicate through holes with a vacuum source and an outer floating cup ring, tiltably mounted over the rigid pickup cup including mean for preventing relative rotation of said floating cup ring and pickup cup, said cup ring having an outer peripheral wall which in the seated position extends below the plane of the bottom face of the rigid pickup cup member to provide a compliant function when the suction mechanism is positioned to pick up a wafer at the wafer loading station.

12. A method for packaging wafers having a bottom side and a top circuit side in containers comprising the steps of;
placing an inverted wafer loaded cassette in an automatic machine for transferring wafers to shipping containers,
horizontally transferring wafers in the cassette to she shipping containers by means of a transfer arm mechanism and removing and transferring wafers from cassettes by means of a vacuum suction mechanism attached to sack transfer arm mechanism and
transferring and discharging the wafer to a container located at a container station and feeding interleafs in timed relation to the wafer feed so that an interleaf is positioned between each wafer loaded in a container.
